(19) United States
(12) Patent Application Publication
(10) Pub. No.: US 2010/0032711 A1
(43) Pub. Date: Feb. 11, 2010

(54) SEMICONDUCTOR DEVICE AND METHOD OF MANUFACTURING THE SAME

(75) Inventors: Shinji Aono, Chiyoda-ku (JP); Junichi Moritani, Chiyoda-ku (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Tokyo (JP)

(21) Appl. No.: 12/344,947

(22) Filed: Dec. 29, 2008

(30) Foreign Application Priority Data
Aug. 11, 2008 (JP) 2008-207250

(51) Int. Cl. H01L 29/739; H01L 21/331

(52) U.S. Cl. 257/139; 438/135; 257/E29.197; 257/E21.382

(57) ABSTRACT

A p-type region is provided on a first n-type region. A second n-type region is provided on the p-type region, spaced apart from the first n-type region by the p-type region. A gate electrode serves to form an n-channel between the first and second n-type regions. A first electrode is electrically connected to each of the p-type region and the second n-type region. A second electrode is provided on the first n-type region such that it is spaced apart from the p-type region by the first n-type region and at least a part thereof is in contact with the first n-type region. The second electrode is made of any of metal and alloy and serves to inject holes into the first n-type region.

### BACKGROUND OF THE INVENTION

1. Field of the Invention

The present invention relates to a semiconductor device and a method of manufacturing the same, and particularly to a semiconductor device having a gate electrode and a method of manufacturing the same.

2. Description of the Background Art

An inverter device has recently been used in such fields as home appliances or industrial power devices. The inverter device normally has a converter portion for rectification and an inverter portion for inversion. In rectification, an alternating-current (AC) voltage obtained from a commercial power supply or the like is converted to a direct-current (DC) voltage. The DC voltage is converted to a desired AC voltage through inversion.

A main power element of the inverter portion desirably has a fast switching speed. Accordingly, a MOSFET (Metal Oxide Semiconductor Field Effect Transistor) or an IGBT (Insulated Gate Bipolar Transistor) in which control is carried out through a gate electrode is mainly used instead of a bipolar transistor. In order to achieve switching at higher speed, electron beam irradiation may be carried out, as disclosed, for example, in B. J. Baliga, “Switching Speed Enhancement in Insulated Gate Transistors by Electron Irradiation,” IEEE Transactions on Electron Devices, Vol. ED-31, No. 12 (1984), pp. 1790-1795.

The IGBT can achieve suppressed ON resistance as compared with the MOSFET. Therefore, the IGBT can be used for the inverter device having a greater capacity. In order to obtain this characteristic, the IGBT has such a structure that the MOSFET and the bipolar transistor are combined, as shown, for example, in Japanese Patent Laying-Open No. 2008-053752.

As described above, though the IGBT can achieve suppressed ON resistance as compared with the MOSFET, it has a more complicated structure.

### SUMMARY OF THE INVENTION

The present invention was made in view of the above-described problems, and an object of the present invention is to provide a semiconductor device of a gate electrode type capable of achieving suppressed ON resistance with a simplified structure as well as a method of manufacturing the same.

A semiconductor device according to the present invention has first and second n-type regions, a p-type region, a gate electrode, and first and second electrodes. The p-type region is provided on the first n-type region. The second n-type region is provided on the p-type region, spaced apart from the first n-type region by the p-type region. The gate electrode is provided on the p-type region with a gate insulating film being interposed. The gate electrode serves to form an n-channel between the first and second n-type regions. The first electrode is electrically connected to each of the p-type region and the second n-type region. The second electrode is provided on the first n-type region such that the second electrode is spaced apart from the p-type region by the first n-type region and at least a part of the second electrode is in contact with the first n-type region. The second electrode is made of any of a metal and an alloy and serves to inject holes into the first n-type region.

A method of manufacturing a semiconductor device according to the present invention includes the following steps.

Initially, a semiconductor substrate having a first n-type region is prepared. A p-type region is formed on the first n-type region. A second n-type region is formed on the p-type region such that it is spaced apart from the first n-type region by the p-type region. A gate electrode for forming an n-channel between the first and second n-type regions is formed on the p-type region with a gate insulating film being interposed. A first electrode is formed such that it is electrically connected to each of the p-type region and the second n-type region. A second electrode made of any of a metal and an alloy for injecting holes into the first n-type region is formed on the first n-type region, such that the second electrode is spaced apart from the p-type region by the first n-type region and at least a part of the second electrode is in contact with the first n-type region.

According to the semiconductor device and the method of manufacturing the same of the present invention, holes can be injected into the first n-type region through the second electrode, without providing a p-type region for injecting holes. Therefore, ON resistance can be suppressed with a simplified structure.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial cross-sectional view schematically showing a configuration of a semiconductor device in a first embodiment of the present invention.

FIG. 2 is a diagram showing an exemplary inverter circuit including the semiconductor device in FIG. 1.

FIG. 3 is a partial cross-sectional view schematically showing a configuration of a semiconductor device in a comparative example.

FIG. 4 is a diagram schematically showing relation between a turn-off speed and an ON voltage of the semiconductor device in the comparative example.

FIG. 5 is a cross-sectional view schematically showing a configuration of a semiconductor device in a second embodiment of the present invention.

FIGS. 6 to 16 are cross-sectional views schematically showing first to eleventh steps in a process of manufacturing the semiconductor device in the second embodiment of the present invention, in the order of steps.

FIG. 17 is a diagram schematically showing relation between a collector-emitter voltage and a collector current density in an example and a comparative example in the present invention.

FIG. 18 is a diagram schematically showing a turn-off waveform of each of a collector current and a collector-emitter voltage when a work function WF is set to 5.2 eV in the example of the present invention.

FIG. 19 is a diagram schematically showing a turn-off waveform of each of a collector current and a collector-emitter voltage when work function WF is set to 5.0 eV in the example of the present invention.

FIG. 20 is a diagram schematically showing relation between a collector-emitter voltage and a collector current density when a carrier lifetime is varied in a range from 10 μs to 0.2 μs in the comparative example.

FIG. 21 is a diagram schematically showing a turn-off waveform of each of a collector current and a collector-emitter voltage when a carrier lifetime is set to 10 μs in the comparative example.

FIG. 22 is a diagram schematically showing a turn-off waveform of each of a collector current and a collector-emitter voltage when a carrier lifetime is set to 0.2 μs in the comparative example.

FIG. 23 is a diagram schematically showing a carrier state when the work function is set to 5.2 eV in the example of the present invention.

FIG. 24 is an enlarged view of a portion at the right end in FIG. 23.

FIG. 25 is a diagram schematically showing a carrier state when the work function is set to 5.1 eV in the example of the present invention.

FIG. 26 is an enlarged view of a portion at the right end in FIG. 25.

FIG. 27 is a diagram schematically showing a carrier state when the work function is set to 5.0 eV in the example of the present invention.

FIG. 28 is an enlarged view of a portion at the right end in FIG. 27.

FIG. 29 is a diagram schematically showing a carrier state when the work function is set to 4.9 eV in the example of the present invention.

FIG. 30 is an enlarged view of a portion at the right end in FIG. 29.

FIG. 31 is a diagram schematically showing a carrier state when the work function is set to 4.8 eV in the example of the present invention.

FIG. 32 is an enlarged view of a portion at the right end in FIG. 31.

FIG. 33 is a diagram schematically showing a carrier state when the work function is set to 4.7 eV in the example of the present invention.

FIG. 34 is an enlarged view of a portion at the right end in FIG. 33.

FIG. 35 is a cross-sectional view schematically showing a structure of a diode used for studying a phenomenon in the example of the present invention.

FIG. 36 is a diagram schematically showing relation between an anode voltage and an anode current in the diode used for studying a phenomenon in the example of the present invention, when the work function is set to 5.2 eV, 5.1 eV, 5.0 eV, 4.9 eV, 4.8 eV, and 4.7 eV.

FIG. 37 is a diagram schematically showing a carrier state when the work function of a Schottky electrode of the diode used for studying a phenomenon in the example of the present invention is set to 5.2 eV.

FIG. 38 is an enlarged view of a portion at the left end in FIG. 37.

FIG. 39 is a diagram schematically showing a carrier state when the work function of the Schottky electrode of the diode used for studying a phenomenon in the example of the present invention is set to 5.1 eV.

FIG. 40 is an enlarged view of a portion at the left end in FIG. 39.

FIG. 41 is a diagram schematically showing a carrier state when the work function of the Schottky electrode of the diode used for studying a phenomenon in the example of the present invention is set to 5.0 eV.

FIG. 42 is an enlarged view of a portion at the left end in FIG. 41.

FIG. 43 is a diagram schematically showing a carrier state when the work function of the Schottky electrode of the diode used for studying a phenomenon in the example of the present invention is set to 4.9 eV.

FIG. 44 is an enlarged view of a portion at the left end in FIG. 43.

FIG. 45 is a diagram schematically showing a carrier state when the work function of the Schottky electrode of the diode used for studying a phenomenon in the example of the present invention is set to 4.8 eV.

FIG. 46 is an enlarged view of a portion at the left end in FIG. 45.

FIG. 47 is a diagram schematically showing a carrier state when the work function of the Schottky electrode of the diode used for studying a phenomenon in the example of the present invention is set to 4.7 eV.

FIG. 48 is an enlarged view of a portion at the left end in FIG. 47.

### DESCRIPTION OF THE PREFERRED EMBODIMENTS

An embodiment of the present invention will be described hereinafter with reference to the drawings.

### First Embodiment

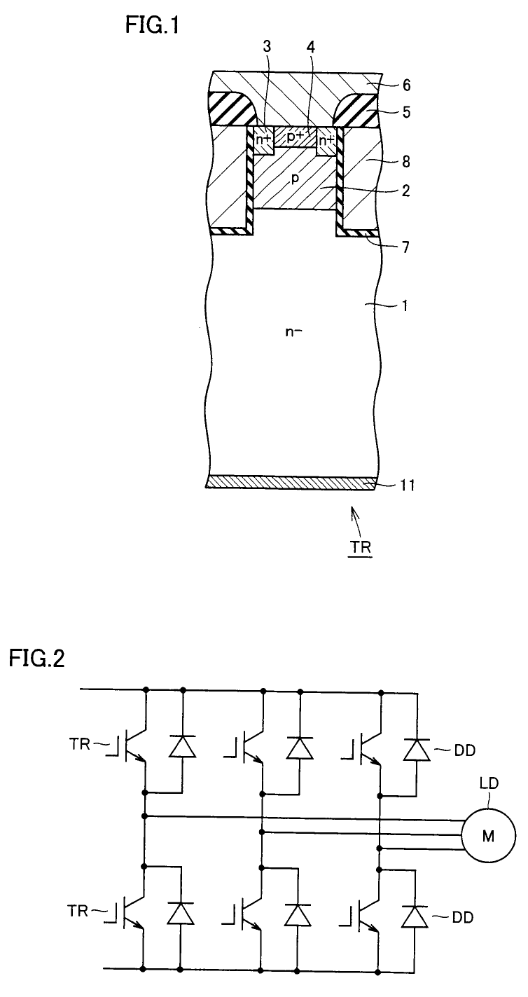

Referring to FIG. 1, a semiconductor device in the present embodiment is an insulating gate type transistor TR. Insulating gate type transistor TR has an n− region 1 (first n-type region), an n-type emitter region 3 (second n-type region), a p base region 2, a p+ contact region 4, a gate insulating film 7, a gate electrode 8, an emitter electrode 6 (first electrode), a collector electrode 11 (second electrode), and an interlayer insulating film 5.

N− region 1 is implemented by an n-type silicon substrate. No electron beam irradiation for decreasing a carrier lifetime is performed on n− region 1.

A p-type region formed of p base region 2 and p+ contact region 4 is provided on n− region 1. In the p-type region, p base region 2 and p+ contact region 4 are located on the n− region 1 side and the emitter electrode 6 side, respectively. P+ contact region 4 is an impurity region higher in concentration than p base region 2.

N-type emitter region 3 is provided on p base region 2, spaced apart from n− region 1 by p base region 2.

Gate electrode 8 is provided on n− region 1, p base region 2, and n-type emitter region 3 with gate insulating film 7 being interposed, such that an n-channel can be formed between n− region 1 and n-type emitter region 3. Gate electrode 8 is made, for example, of polysilicon. In addition, the gate electrode in the present embodiment has a trench gate structure. Namely, gate electrode 8 is formed in a trench with gate insulating film 7 being interposed. The trench reaches n− region 1 through n-type emitter region 3 and p base region 2.

Emitter electrode 6 is electrically connected to each of p+ contact region 4 and n-type emitter region 3.

Collector electrode 11 is provided on n− region 1 such that it is spaced apart from p base region 2 by n− region 1 and at least a part thereof is in contact with n− region 1. Preferably, a region made of a p-type semiconductor is not provided between collector electrode 11 and n− region 1.

Collector electrode 11 is made of any of a metal and an alloy and has a function to inject holes into n− region 1. In order to sufficiently inject holes, collector electrode 11 has a work function not lower than 4.8 eV. In addition, preferably, collector electrode 11 has a work function lower than 5.3 eV.

For example, platinum silicide (PtSi) may be used as a material having a work function not lower than 4.8 eV and less than 5.3 eV. It is noted that a platinum silicide layer may be provided on n− region 1 and another layer may further be provided on the platinum silicide layer. A layered material such as Ti/Ni/Au may be used as a material for this layer.

Interlayer insulating film 5 insulates emitter electrode 6 from gate electrode 8.

In insulating gate type transistor TR, for example, boron and arsenic may be used as impurities for attaining conductivity types of p and n, respectively.

A basic operation of insulating gate type transistor TR will now be described.

First, a turn-on operation will be described. A prescribed voltage is applied across emitter electrode 6 and collector electrode 11 such that collector electrode 11 is higher in potential than emitter electrode 6. In this state, positive bias not lower than a threshold value is applied to gate electrode 8. Insulating gate type transistor TR thus conducts in a forward direction.

Second, a turn-off operation will be described. Negative bias is applied to gate electrode 8. Then, a depletion layer extends from p base region 2 toward the n− region, so that a withstand voltage is maintained.

Referring to FIG. 2, this inverter circuit is a full-bridge circuit, and has insulating gate type transistor TR, a free-wheeling diode DD, and an inductive load LD. Inductive load LD is connected to an intermediate potential point between upper and lower arms, and a current flows both in a positive direction and in a negative direction. Accordingly, the current that flows through inductive load LD is returned from a load connection end to a power supply side at high potential or flows toward a ground side. Therefore, free-wheeling diode DD for returning a large current that flows through inductive load LD between inductive load LD and a closed circuit in the arm is connected.

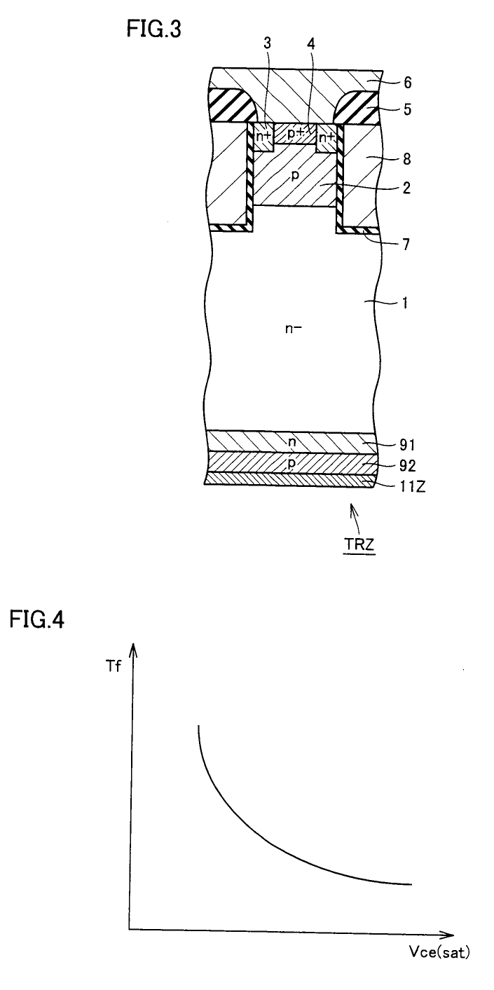

Referring to FIG. 3, a semiconductor device in the present comparative example is an insulating gate type bipolar transistor TRZ. Insulating gate type bipolar transistor TRZ has an n-type buffer region 91, a p-type collector region 92, and a collector electrode 11Z on n− region 1. P-type collector region 92 has a function as a source for supplying holes to the n− region.

Referring to FIG. 4, an ON voltage Vce (sat) is substantially inversely proportional to a turn-off speed Tf In order to suppress turn-off speed Tf of insulating gate type bipolar transistor TRZ, for example, n− region 1 is irradiated with electron beams for decreasing a carrier lifetime.

According to the present embodiment, it is not necessary to provide p-type collector region 92 (FIG. 3) in insulating gate transistor TR (FIG. 1), unlike insulating gate type bipolar transistor TRZ (FIG. 3). Therefore, the structure is simplified.

In addition, at the time of turn-on, holes are injected from collector electrode 11 (FIG. 1) to n− region 1, for conductivity modulation of n− region 1. As electric resistance of n− region 1 is thus lowered, ON resistance of insulating gate type transistor TR can be suppressed.

In addition, as collector electrode 11 has a work function not lower than 4.8 eV, sufficient injection of holes into n− region 1 is carried out. ON resistance of insulating gate type transistor TR can thus sufficiently be suppressed.

In addition, collector electrode 11 has a work function less than 5.3 eV. Therefore, without electron beam irradiation of n− region 1 for decreasing a carrier lifetime, the turn-off speed can be increased. Namely, the turn-off operation can be performed at high speed. Therefore, electron beam irradiation is not performed, and the process is correspondingly simplified.

In addition, platinum silicide is used as a material for collector electrode 11. Collector electrode 11 having a work function not lower than 4.8 eV and less than 5.3 eV can thus be formed.

In addition, as gate electrode 8 has a trench gate structure, ON resistance lower than in the case of a planar gate structure can be achieved.

Moreover, p+ contact region 4 higher in concentration than p base region 2 is provided between emitter electrode 6 and p base region 2. As a contact resistance of emitter electrode 6 is thus lowered, ON resistance can be lowered.

Further, preferably, a region made of a p-type semiconductor is not provided between collector electrode 11 and n− region 1. Accordingly, the step of forming a region made of a p-type semiconductor on n− region 1 on the collector electrode 11 side is no longer necessary. As the step of injecting and diffusing a p conductivity type impurity into the collector electrode 11 side of n− region 1 is thus no longer necessary, the manufacturing process is simplified.

### Second Embodiment

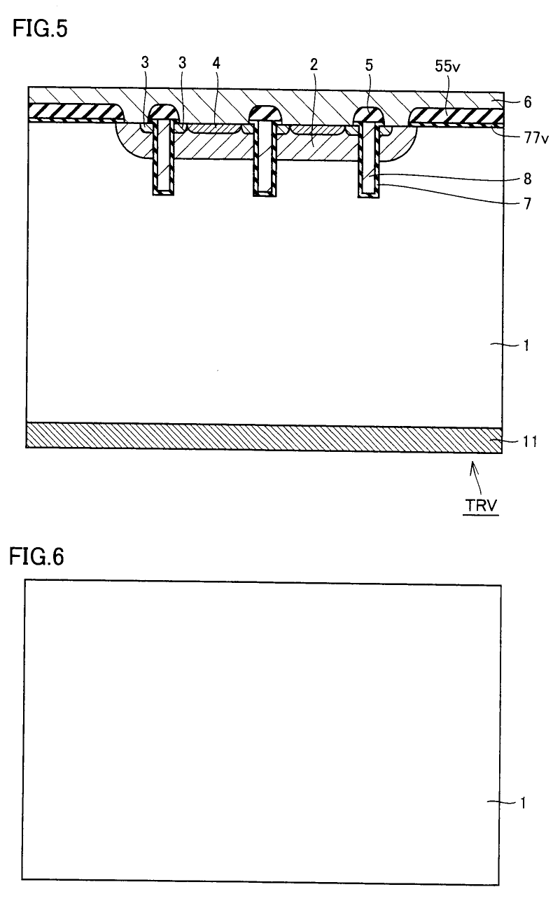

Referring to FIG. 5, a semiconductor device in the present embodiment is an insulating gate type transistor TRV, and has a configuration substantially similar to that of insulating gate type transistor TR (FIG. 1) according to the first embodiment. In addition, insulating gate type transistor TRV has a layered film formed of an insulating film 77V and an interlayer insulating film 55v. The layered film insulates n− region 1 from emitter electrode 6.

As the configuration is otherwise substantially the same as in the first embodiment described above, the same or corresponding elements have the same reference characters allotted and detailed description thereof will not be repeated.

The process of manufacturing the semiconductor device in the second embodiment of the present invention will now be described.

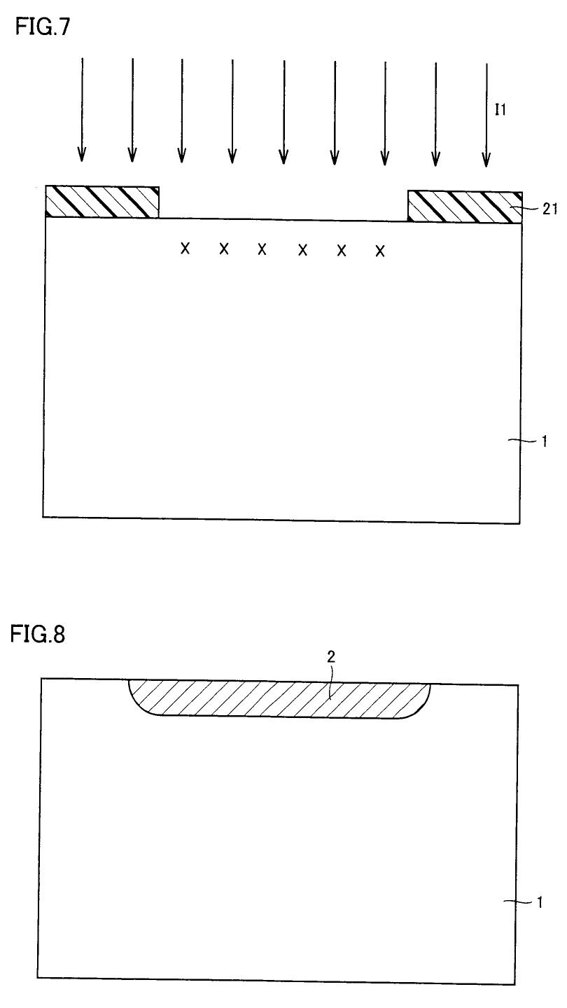

Referring to FIG. 6, an n-type silicon substrate having n− region 1 is prepared.

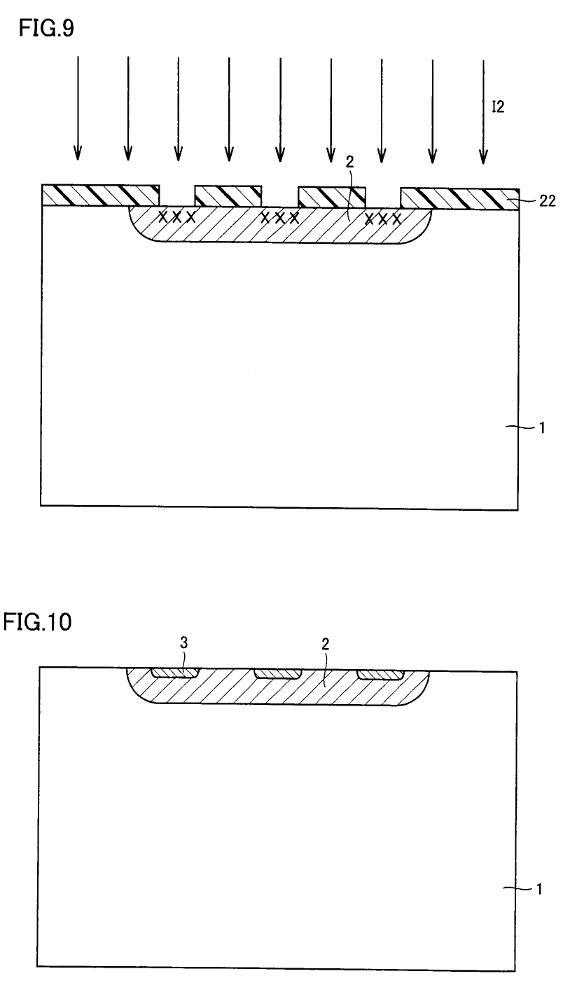

Referring to FIG. 7, a resist pattern 21 is formed on n− region 1. As a result of impurity injection 11 using resist pattern 21 as a mask, a p conductivity type impurity (X in the figure) is selectively injected onto n− region 1. For example, boron (B) is adopted as the impurity. Resist pattern 21 is then removed.

Referring to FIG. 8, p base region 2 is formed on n− region 1 as a result of diffusion of the impurity above.

Referring to FIG. 9, a resist pattern 22 is formed on n− region 1 and p base region 2. As a result of impurity injection 12 using resist pattern 22 as a mask, an n conductivity type impurity (X in the figure) is selectively injected onto p base region 2. For example, arsenic (As) is adopted as the impurity. Resist pattern 22 is then removed.

Referring to FIG. 10, n-type emitter region 3 is formed on p base region 2 as a result of diffusion and activation of the impurity above.

Referring to FIG. 11, a trench reaching n− region 1 through each of p base region 2 and n-type emitter region 3 is formed in a surface implemented by n− region 1, p base region 2, and n-type emitter region 3. Thereafter, insulating film 77 covering the surface and an inner surface of the trench is formed.

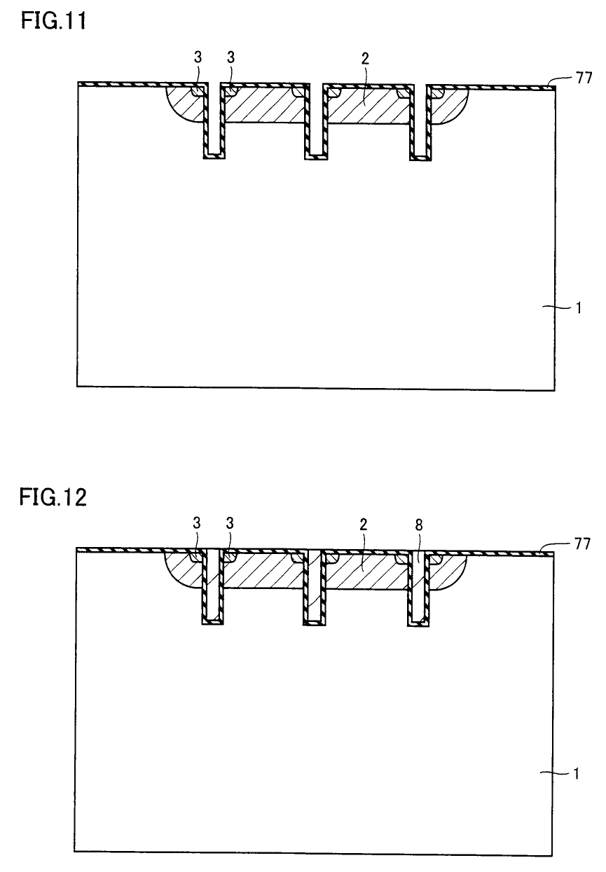

Referring to FIG. 12, the trench is filled with conductive polysilicon with insulating film 77 being interposed, so as to form gate electrode 8. Thereafter, an interlayer insulating film (not shown in FIG. 12) is formed. The layered film formed of this interlayer insulating film and insulating film 77 is patterned.

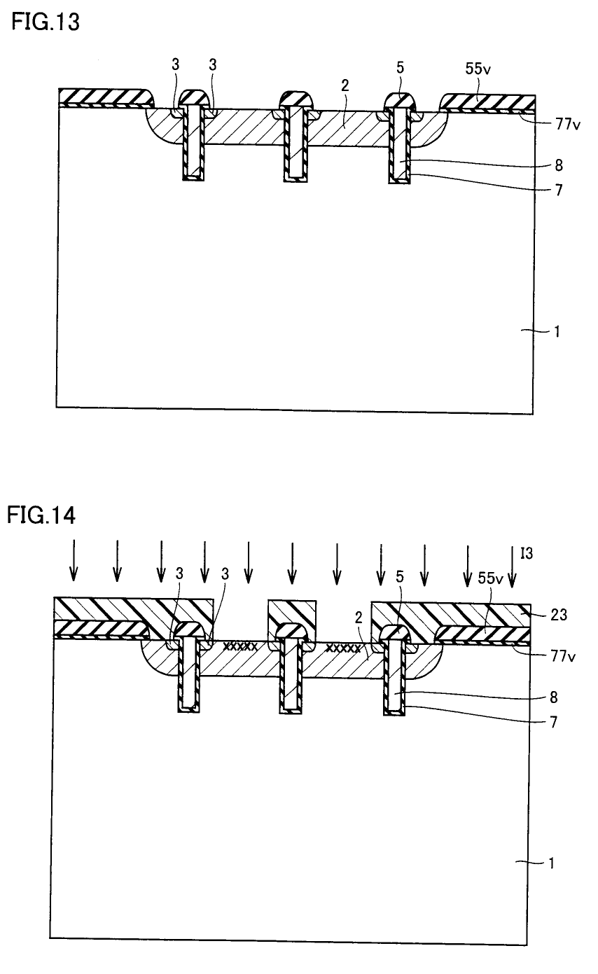

Referring to FIG. 13, as a result of patterning above, interlayer insulating film 55v exposing p base region 2 and n-type emitter region 3 but covering gate electrode 8 is formed. In addition, gate insulating film 7 and insulating film 77v are formed from insulating film 77.

Referring to FIG. 14, as a result of impurity injection 13 using a resist pattern 23 exposing p base region 2 as a mask, a p conductivity type impurity (X in the figure) is selectively injected onto p base region 2. For example, boron (B) is adopted as the impurity. Resist pattern 23 is then removed.

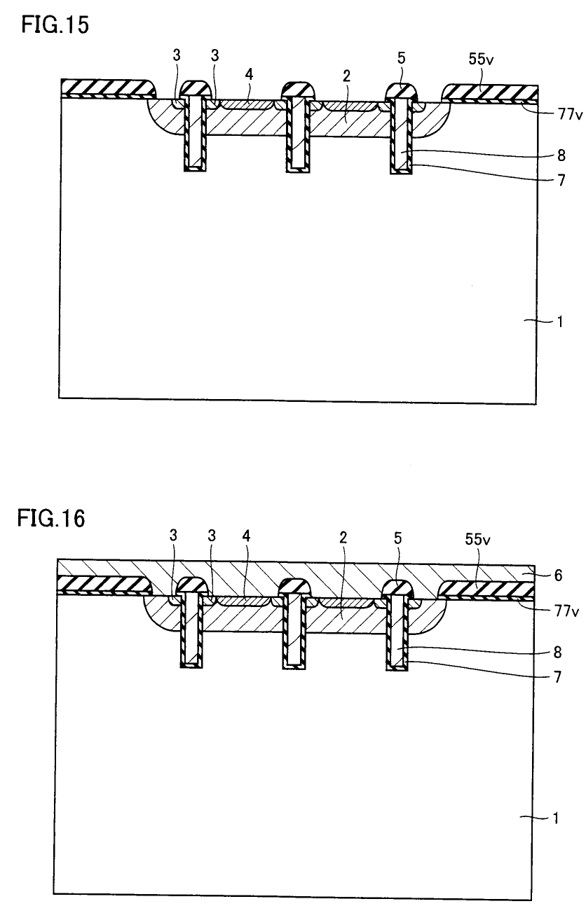

Referring to FIG. 15, as a result of activation of the impurity above, p+ contact region 4 is formed on p base region 2.

Referring to FIG. 16, emitter electrode 6 is formed such that it is electrically connected to each of n-type emitter region 3 and p+ contact region 4.

Referring again to FIG. 5, collector electrode 11 is formed such that it is spaced apart from p base region 2 by n− region 1. Specifically, initially, a platinum (Pt) layer is formed on the n− region 1 with a sputtering method. Thereafter, heat treatment is performed so that silicidation of platinum formed with the sputtering method and silicon included in n− region 1 takes place to form a platinum silicide layer.

Instead of the method of causing silicidation through heat treatment as described above, a platinum silicide layer may directly be deposited with a sputtering method or a vapor deposition method.

Insulating gate type transistor TRV according to the present embodiment is obtained as described above.

### EXAMPLE

The present invention will be described hereinafter in further detail with reference to examples, however, the present invention is not limited thereto.

A simulation result in a case where work function WF of collector electrode 11 of insulating gate type transistor TR (FIG. 1) is in a range from 4.8 to 5.2 eV will be described as an example of the present invention. In addition, a simulation result in a case where work function WF of collector electrode 11 of insulating gate type transistor TR (FIG. 1) is in a range from 4.2 to 4.6 eV and in a case where insulating gate type bipolar transistor TRZ (FIG. 3) is employed will be described as a comparative example of the present invention.

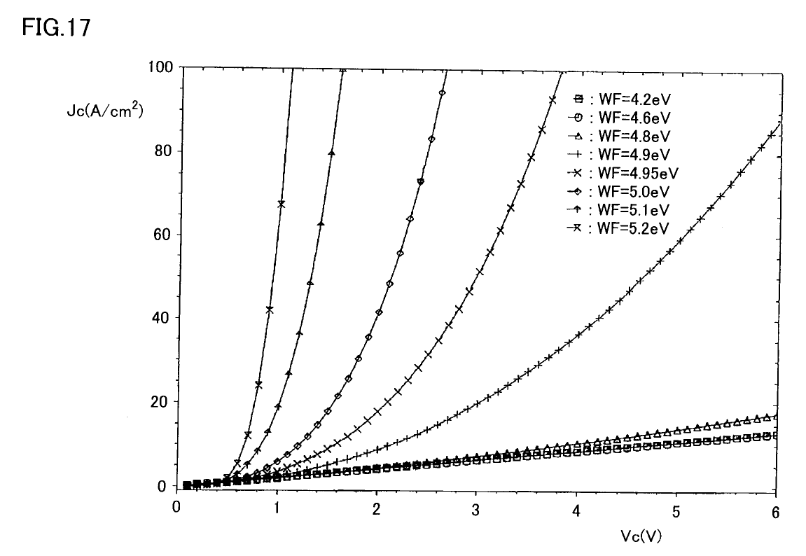

Referring to FIG. 17, relation between a collector-emitter voltage Vc and a collector current density Jc was simulated for a case where work function WF of collector electrode 11 of insulating gate type transistor TR (FIG. 1) was varied in a range from 4.2 eV to 5.2 eV. When work function WF was increased from 4.2 eV to 4.6 eV, variation in collector current density Jc was not observed. When work function WF was increased from 4.6 eV to 4.8 eV, noticeable increase in collector current density Jc was observed. When work function WF was increased from 4.8 eV to 4.9 eV, further noticeable increase in collector current density Jc was observed. As work function WF was further increased toward 5.2 eV, collector current density Jc increased. Namely, when work function WF is set to 4.8 eV or higher, ON resistance of insulating gate type transistor TR was significantly suppressed, and when work function WF was set to 4.9 eV or higher, it was more significantly suppressed.

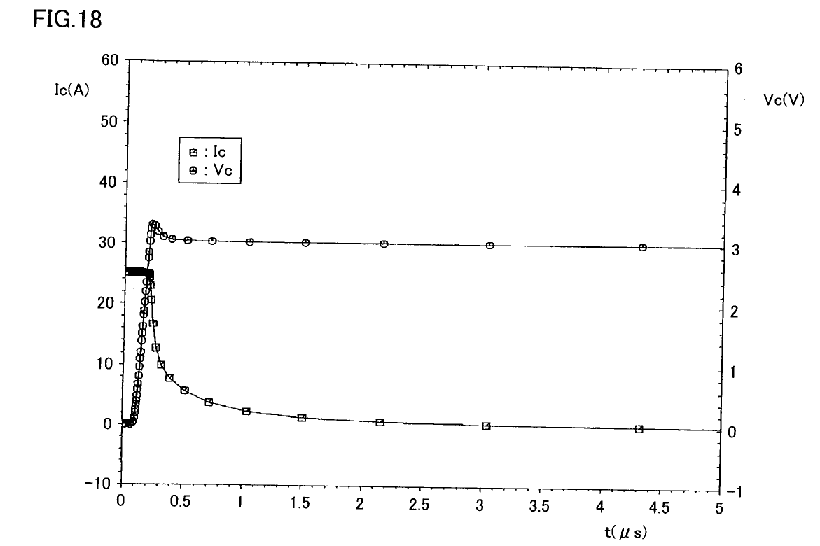

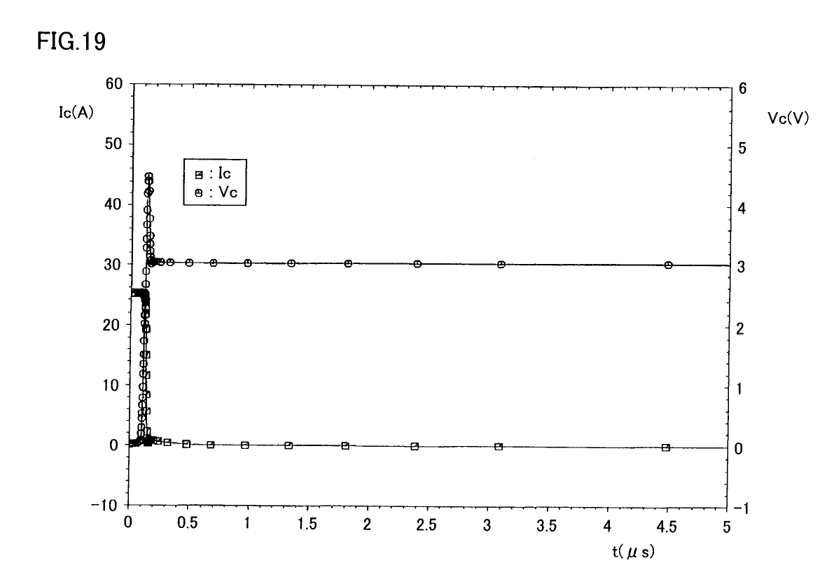

Referring to FIGS. 18 and 19, a turn-off time was simulated with a carrier lifetime being set to 10 μs for a case where work function WF was set to 5.2 eV (FIG. 18) and to 5.0 eV (FIG. 19). A case where lifetime control such as electron beam irradiation was not carried out was assumed by setting the carrier lifetime to 10 μs. According to a result of simulation, the turn-off times were 2 μs and 0.2 μs when work function WF was set to 5.2 eV and 5.0 eV, respectively.

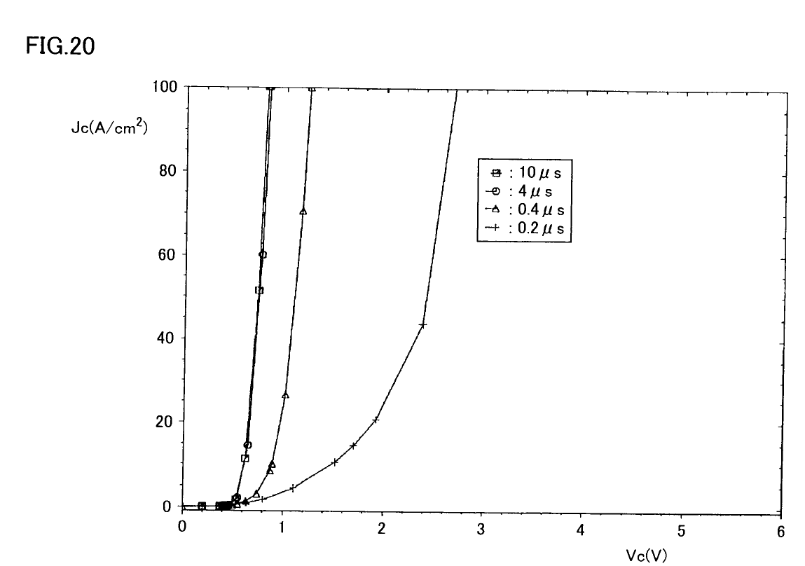

Referring mainly to FIG. 20, relation between collector-emitter voltage Vc and collector current density Jc was simulated for a case where a carrier lifetime of n− region 1 of insulating gate type bipolar transistor TRZ (FIG. 3) representing a comparative example was varied in a range from 10 μs to 0.2 μs. When the carrier lifetime is decreased from 10 μs to 0.2 μs through electron beam irradiation or the like, collector current density Jc was lowered.

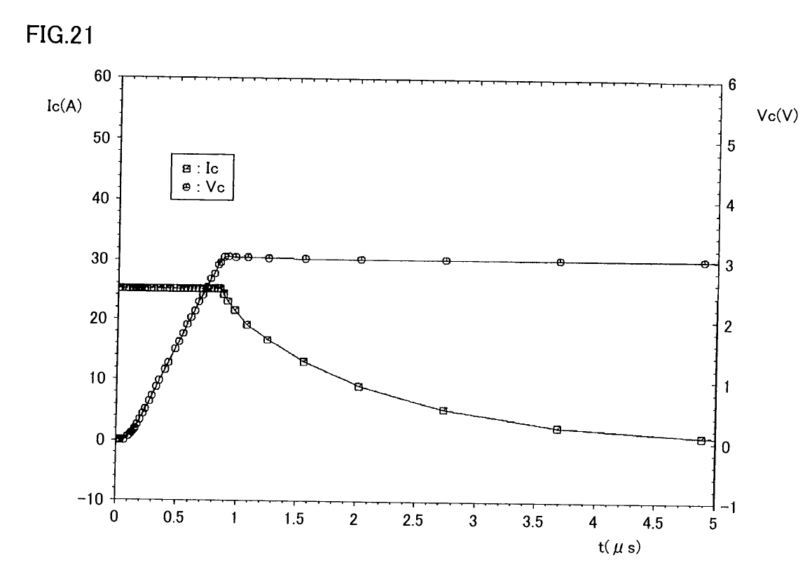

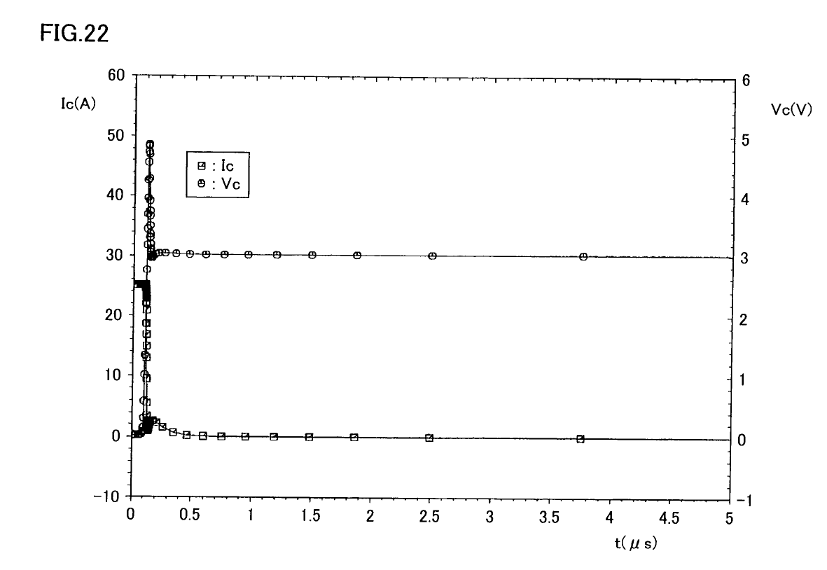

Referring to FIGS. 20 to 22, the turn-off time was simulated for a case where a carrier lifetime of insulating gate type bipolar transistor TRZ (FIG. 3) representing a comparative example was set to 10 μs (FIG. 21) and 0.2 μs (FIG. 22). According to a result of simulation, when the carrier lifetime was set to 10 μs, collector-emitter voltage Vc was approximately 0.8 V (FIG. 20) with collector current density Jc=100 A/cm² and the turn-off time was approximately 5 μs (FIG. 21). In addition, when the carrier lifetime was decreased from 10 μs to 0.2 μs through electron beam irradiation or the like, collector-emitter voltage Vc was approximately 2.7 V (FIG. 20) with collector current density Jc=100 A/cm² and the turn-off time was approximately 0.2 μs (FIG. 22).

Therefore, if treatment for suppressing a carrier lifetime through electron beam irradiation or the like is not performed, the turn-off time of insulating gate type bipolar transistor TRZ (FIG. 3) representing the comparative example was 5 μs (FIG. 21), and a longer time than in the present example was required for turn-off. Therefore, in order to achieve a turn-off time in insulating gate type bipolar transistor TRZ (FIG. 3) as long as that in the present example, treatment for suppressing a carrier lifetime was required in the manufacturing process, which complicated the manufacturing process.

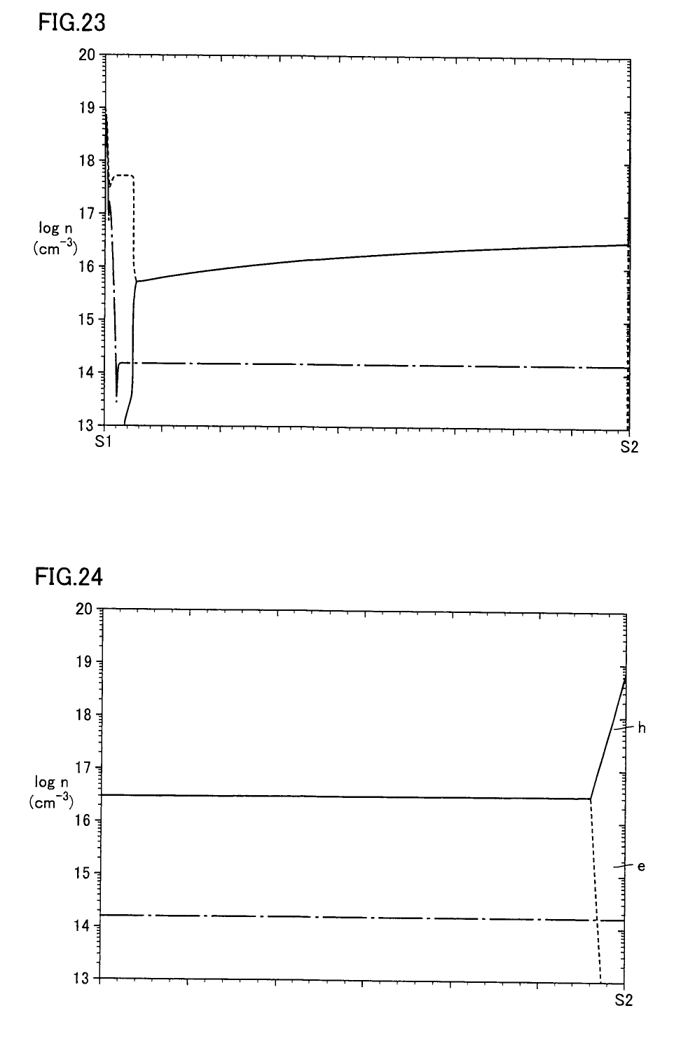

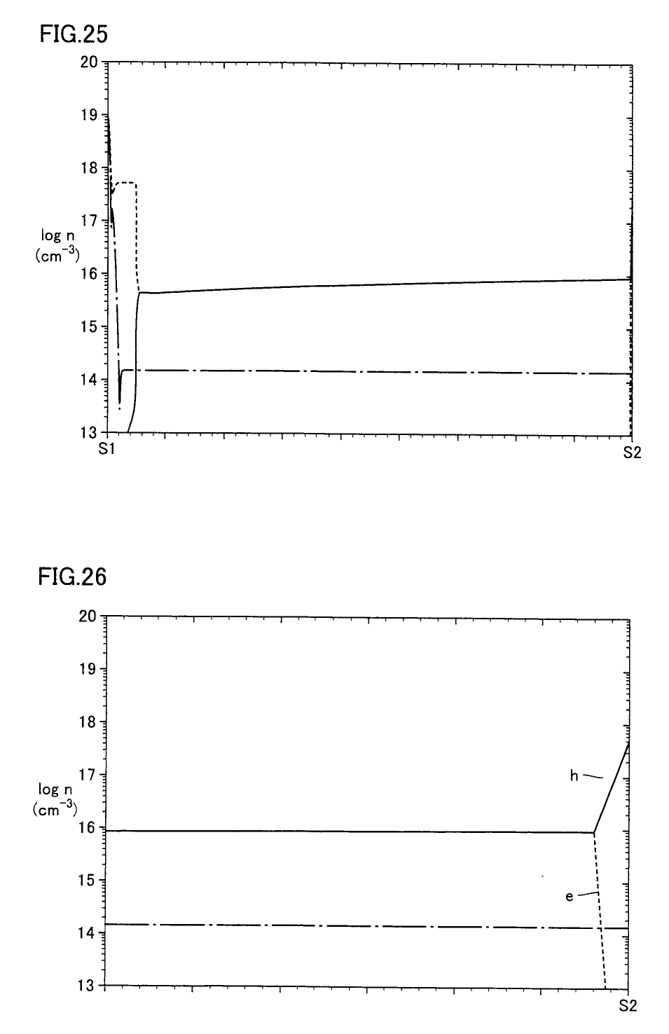

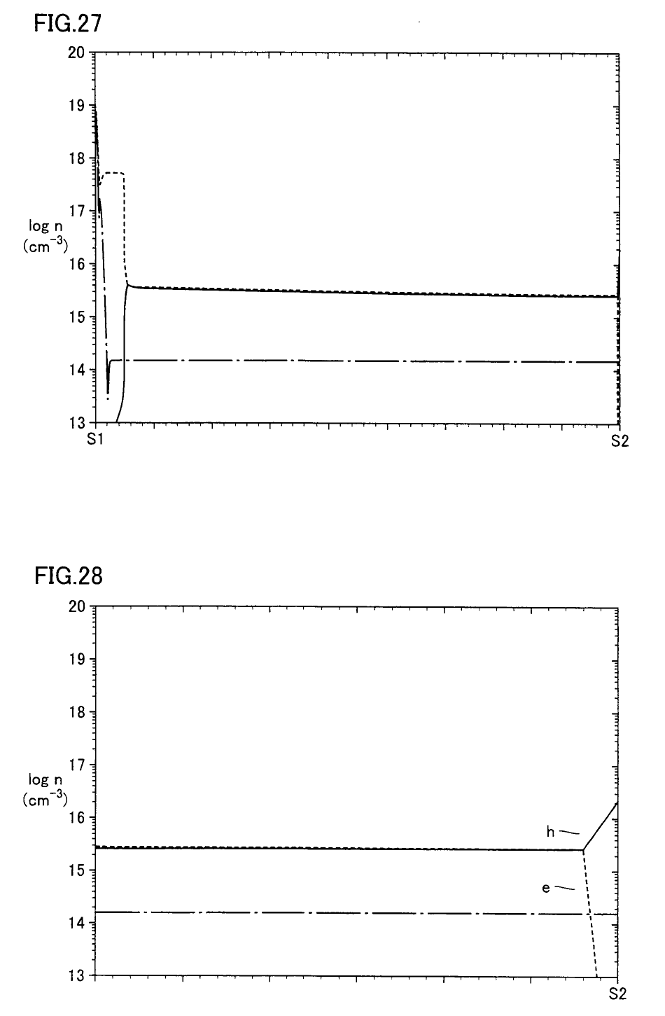

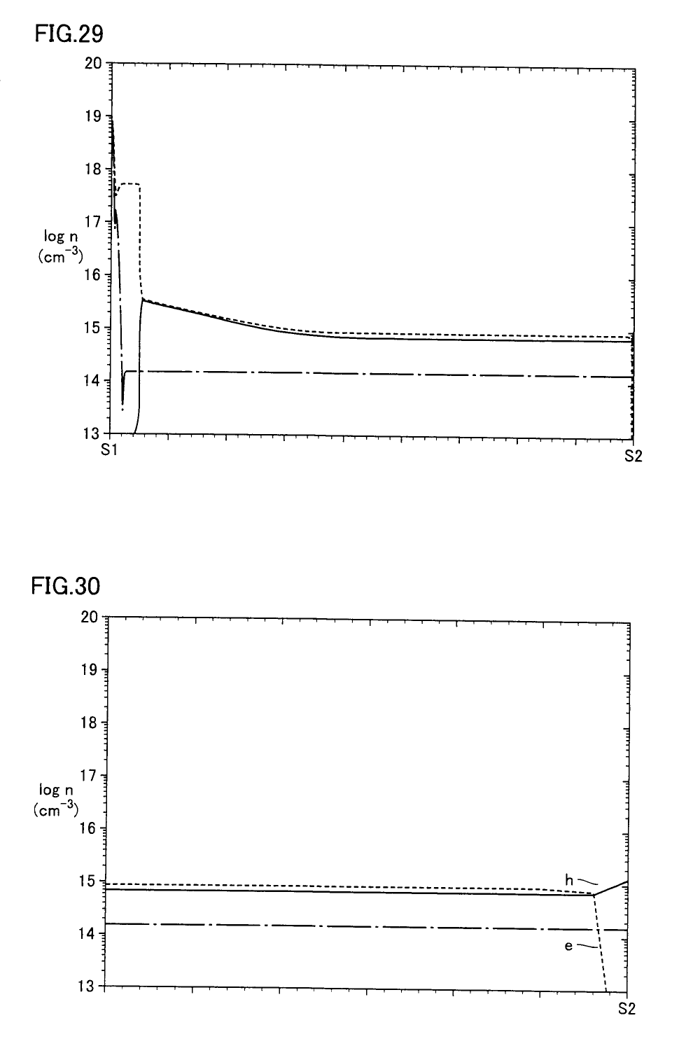

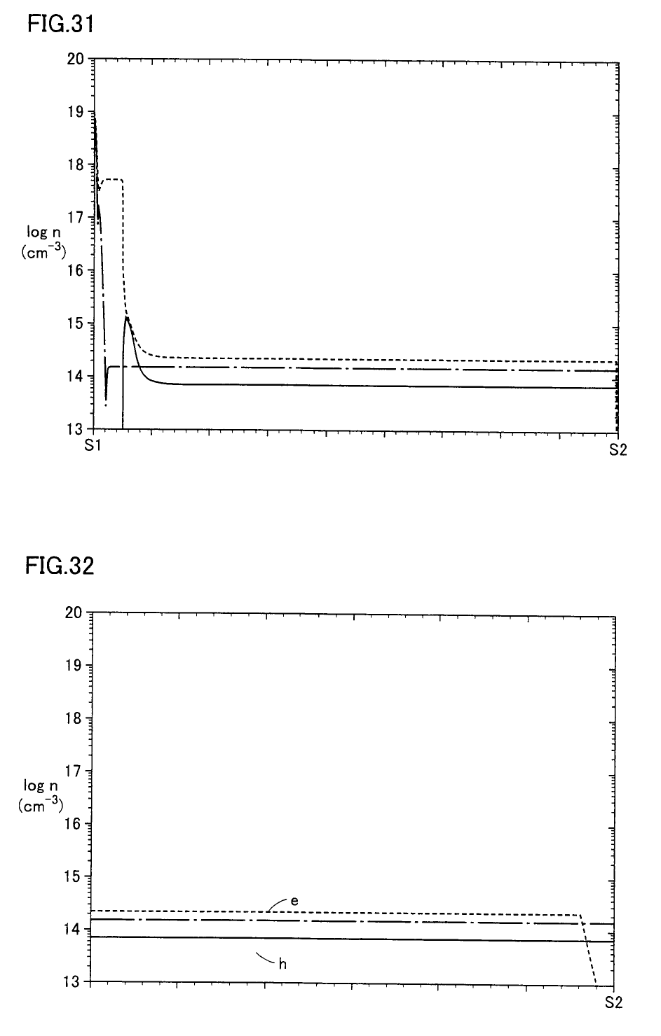

Relation between work function WF of insulating gate type transistor TR (FIG. 1) and carrier distribution will now be described with reference to FIGS. 23 to 34.

In the figures, an interface S1 and an interface S2 show an interface position with emitter electrode 6 of a semiconductor region of insulating gate type transistor TR (FIG. 1) and an interface position with collector electrode 11 thereof In addition, log n on the ordinate shows each of a hole concentration, an electron concentration, and an impurity concentration in a logarithmic scale. The hole concentration, the electron concentration, and the impurity concentration are shown in the figures with a solid line, a dashed line and a chain-dotted line, respectively.

Referring to FIGS. 23 to 32, in the present example, that is, in the example where work function WF is in a range from 4.8 eV to 5.2 eV, holes (solid line h in the figure) were produced from interface S2 to the inside of n− region 1. It seems that these holes contributed to conductivity modulation of n− region 1.

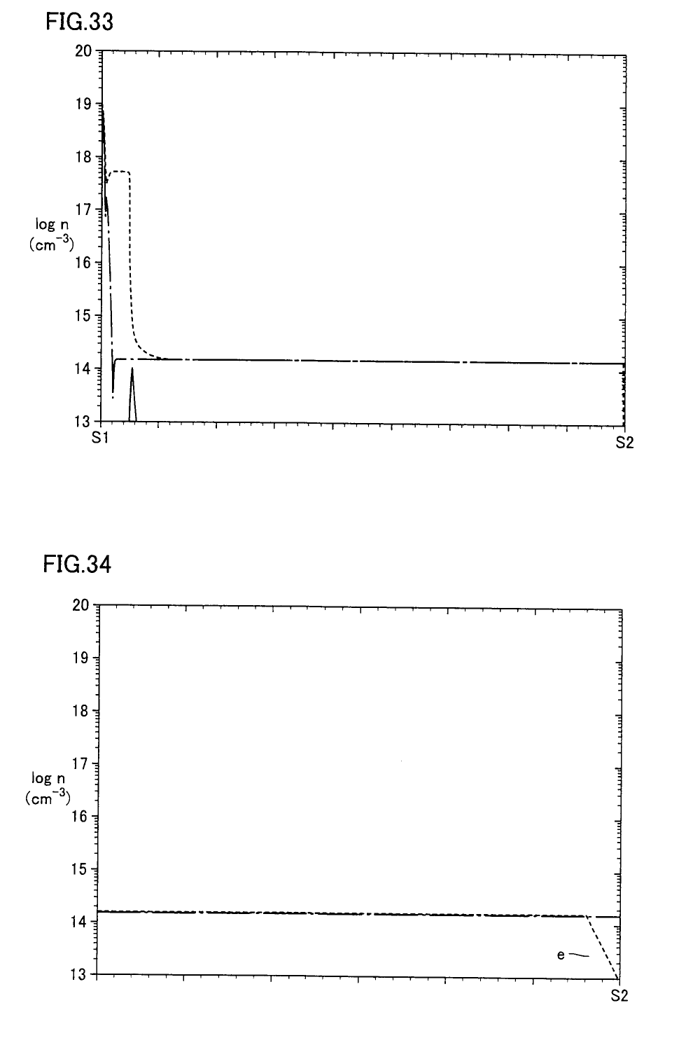

Referring to FIGS. 33 and 34, in the comparative example, that is, in the example where work function WF was set to 4.7 eV, holes (solid line h in the figure) were not produced from interface S2 to the inside of n− region 1. Accordingly, it seems that conductivity modulation did not occur in n− region 1.

It was found from the result of simulation of carrier distribution in insulating gate type transistor TR above that a value of work function WF=4.8 eV is a critical point as to whether holes are present in n− region 1 or not. In other words, it was found that work function WF=4.8 eV is a critical point in achieving low ON resistance based on utilization of holes as carriers by insulating gate type transistor TR.

In order to understand a phenomenon in the present example, a result of simulation done for a diode having a structure more simplified than in insulating gate type transistor TR will now be described.

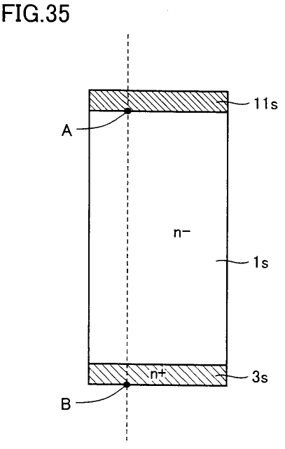

Referring mainly to FIG. 35, the diode has an n− region 1s, a Schottky electrode 11s, and an n+ layer 3s. Schottky electrode 11s and n+ layer 3s are formed on opposing ends of n− region 1s, respectively. Schottky electrode 11s is made of a material the same as that for collector electrode 11 (FIG. 1), and has a function as an anode electrode. In addition, n+ layer 3s has a function as a cathode electrode.

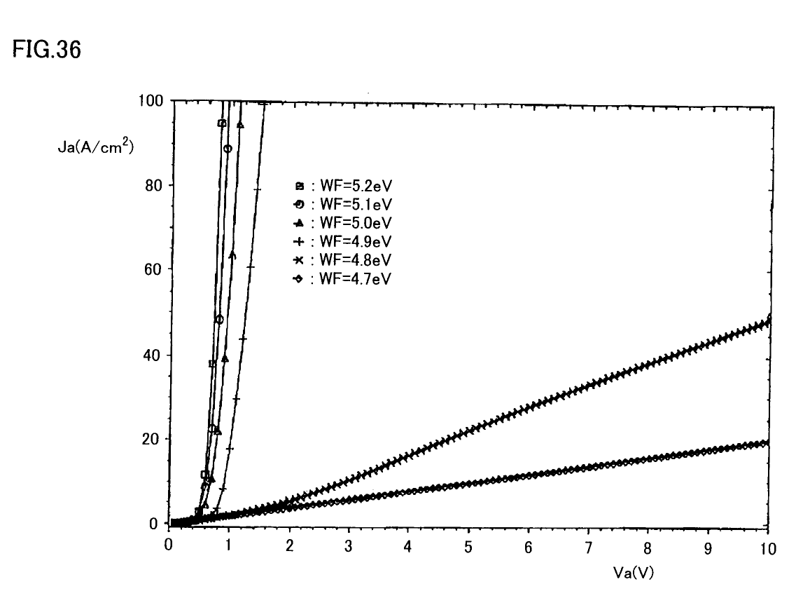

Referring to FIG. 36, relation between an anode voltage Va and anode current density Ja was simulated for a case where work function WF of Schottky electrode 11s was varied in a range from 4.7 eV to 5.2 eV. When work function WF was increased from 4.7 eV to 4.8 eV, significant increase in anode current density Ja was observed. When work function WF was increased from 4.8 eV to 4.9 eV, further significant increase in anode current density Ja was observed. As work function WF was further increased toward 5.2 eV, anode current density Ja increased. Namely, when work function WF is set to 4.8 eV or higher, lowering in a forward voltage was significantly suppressed, and when it is set to 4.9 eV or higher, lowering in a forward voltage was further significantly suppressed. It seems that suppression of voltage lowering was achieved by conductivity modulation.

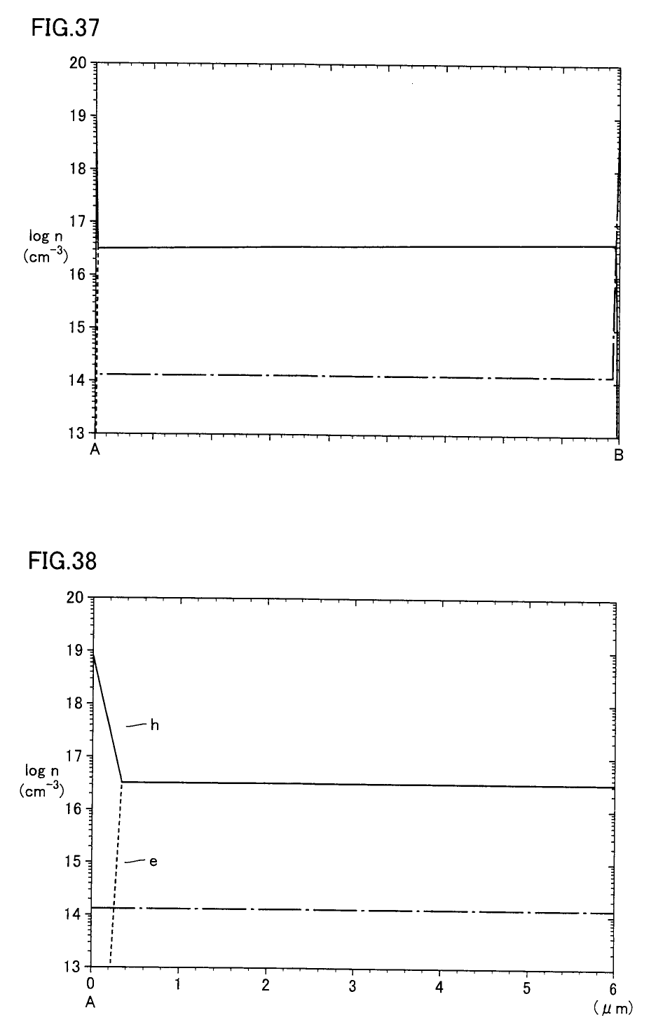

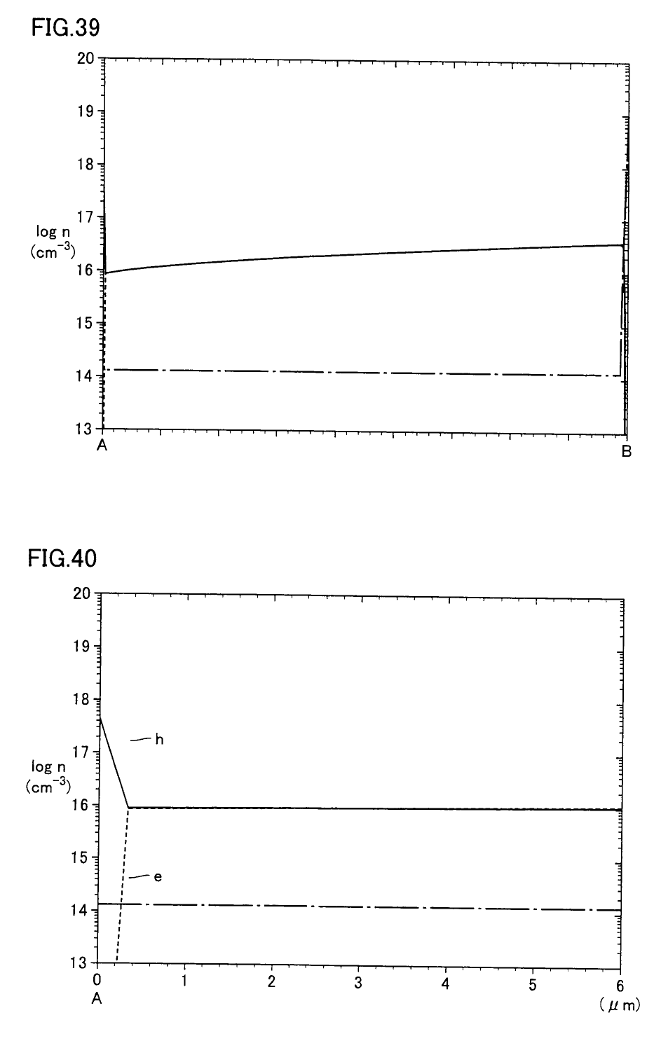

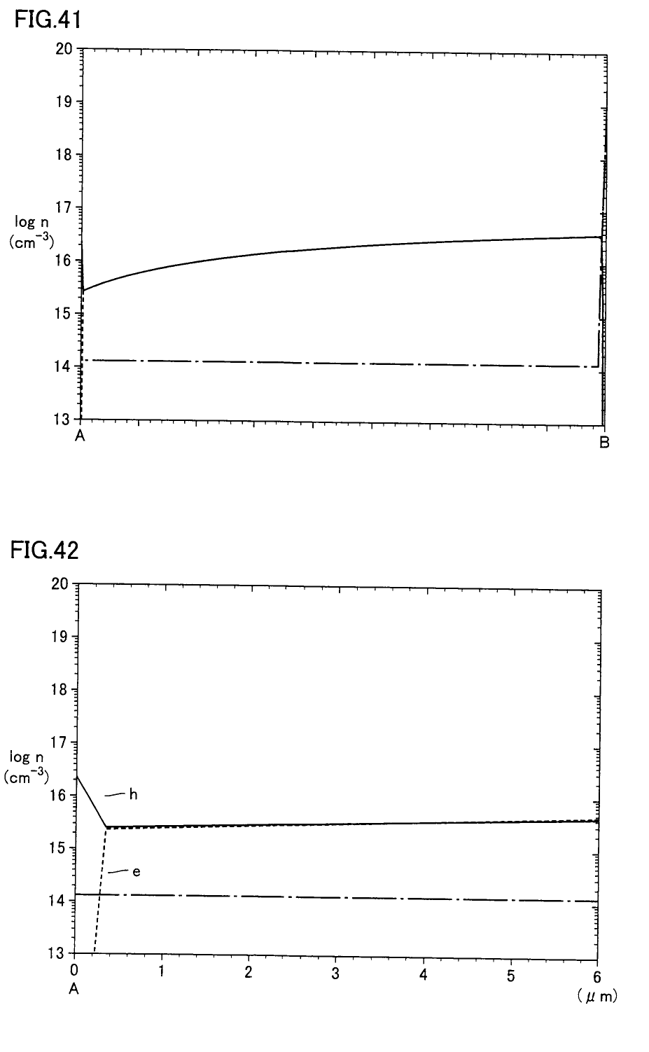

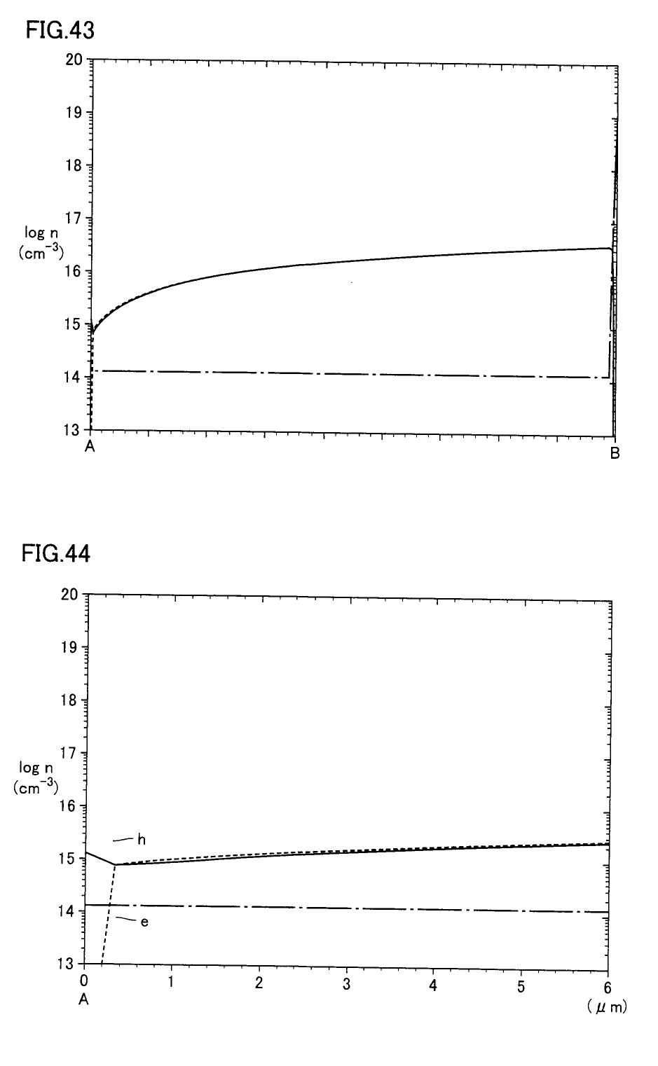

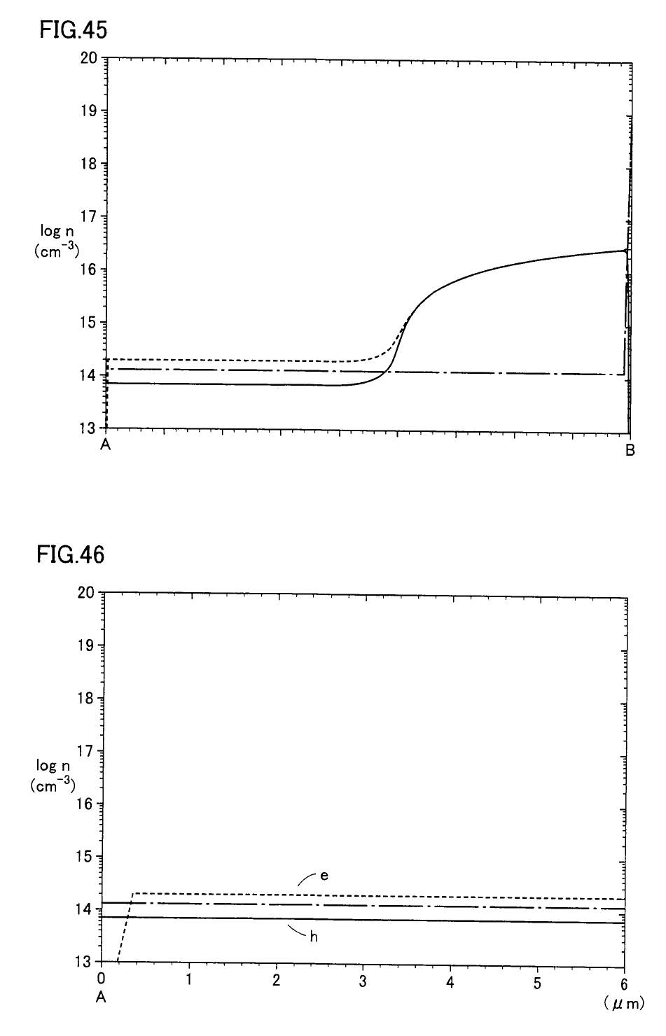

Relation between work function WF of the diode above and carrier distribution will now be described with reference to FIGS. 37 to 48.

In the figures, a position A and a position B correspond to a position A and a position B of the diode (FIG. 35), respectively. In addition, log n on the ordinate shows each of a hole concentration, an electron concentration, and an impurity concentration in a logarithmic scale. The hole concentration, the electron concentration, and the impurity concentration are shown in the figures with a solid line, a dashed line and a chain-dotted line, respectively.

Referring to FIGS. 37 to 46, when work function WF is in a range from 4.8 eV to 5.2 eV, conductivity type of n− region 1 was inverted from n-type to p-type at a location of Schottky barrier of Schottky electrode 11s, and holes (solid line h in the figures) were produced from position A to the inside of n− region 1s. It seems that these holes contributed to conductivity modulation.

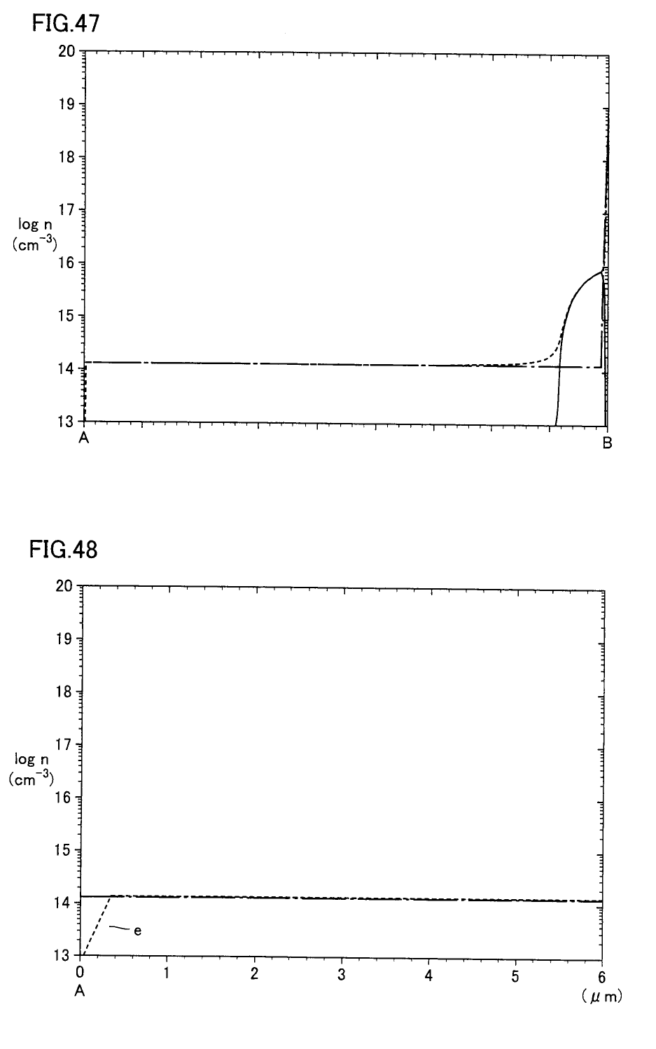

Referring to FIGS. 47 and 48, when work function WF was set to 4.7 eV, holes (solid line h in the figure) were not produced from position A to the inside of n− region 1s. Accordingly, it seems that conductivity modulation did not occur in n− region 1s.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device, comprising:
a first n-type region;
a p-type region provided on said first n-type region;
a second n-type region provided on said p-type region, spaced apart from said first n-type region by said p-type region;
a gate electrode provided on said p-type region with a gate insulating film being interposed, for forming an n-channel between said first and second n-type regions;
a first electrode electrically connected to each of said p-type region and said second n-type region; and
a second electrode provided on said first n-type region such that the second electrode is spaced apart from said p-type region by said first n-type region and at least a part of the second electrode is in contact with said first n-type region, said second electrode being made of any of a metal and an alloy and serving to inject holes into said first n-type region.

2. The semiconductor device according to claim 1, wherein
said second electrode has a work function not lower than 4.8 eV.

3. The semiconductor device according to claim 1, wherein
said second electrode includes a platinum silicide layer.

4. The semiconductor device according to claim 1, wherein
no region made of a p-type semiconductor is provided between said second electrode and said first n-type region.

5. The semiconductor device according to claim 1, wherein
said gate electrode has a trench gate structure.

6. The semiconductor device according to claim 1, wherein
said p-type region includes
a first p-type region located on a side of said first n-type region, and
a second p-type region located on a side of said first electrode and being higher in concentration than said first p-type region.

7. A method of manufacturing a semiconductor device, comprising the steps of:
preparing a semiconductor substrate having a first n-type region,
forming a p-type region on said first n-type region;
forming a second n-type region on said p-type region such that the second n-type region is spaced apart from said first n-type region by said p-type region;
forming, on said p-type region with a gate insulating film being interposed, a gate electrode for forming an n-channel between said first and second n-type regions;
forming a first electrode such that the first electrode is electrically connected to each of said p-type region and said second n-type region; and
forming, on said first n-type region, a second electrode made of any of a metal and an alloy, for injecting holes into said first n-type region, such that the second electrode is spaced apart from said p-type region by said first n-type region and at least a part of the second electrode is in contact with said first n-type region.

8. The method of manufacturing a semiconductor device according to claim 7, wherein
said second electrode has a work function not lower than 4.8 eV.

9. The method of manufacturing a semiconductor device according to claim 7, wherein
said second electrode includes a platinum silicide layer.

10. The method of manufacturing a semiconductor device according to claim 9, wherein
said first n-type region includes silicon, and
said step of forming a second electrode includes the steps of forming a metal layer including platinum on said first n-type region, and forming said platinum silicide layer by causing platinum included in said metal layer and silicon included in said n-type region to react with each other.

11. The method of manufacturing a semiconductor device according to claim 9, wherein
said step of forming a second electrode includes the step of depositing said platinum silicide layer on said first n-type region with any of a vapor deposition method and a sputtering method.

12. The method of manufacturing a semiconductor device according to claim 7, wherein
no region made of a p-type semiconductor is formed between said second electrode and said first n-type region.

13. The method of manufacturing a semiconductor device according to claim 7, wherein
said step of forming a gate electrode includes the steps of
forming a trench having an inner surface at which each of said first and second n-type regions and said p-type region is exposed,
forming said gate insulating film so as to cover said inner surface, and
forming said gate electrode on said gate insulating film.

14. The method of manufacturing a semiconductor device according to claim 7, wherein
said step of forming a p-type region includes the steps of forming a first p-type region on said first n-type region and forming a second p-type region higher in concentration than said first p-type region above said first n-type region, and
said step of forming a first electrode is performed by forming said first electrode such that the first electrode is electrically connected to each of said second p-type region and said second n-type region.
